(19) United States
(12) Patent Application Publication
(10) Pub. No.: US 2025/0096185 A1
(43) Pub. Date: Mar. 20, 2025

(54) THERMAL DISSIPATION IN SEMICONDUCTOR DEVICES

(71) Applicant: Taiwan Semiconductor Manufacturing Company, Ltd., Hsinchu (TW)

(72) Inventors: Po-Yu Chen, Hsinchu (TW); Cheng Hung Wu, Hsinchu (TW); Hui-Ling Lin, Hsinchu (TW); Yu Hsiang Chen, Hsinchu (TW)

(73) Assignee: Taiwan Semiconductor Manufacturing Company, Ltd., Hsinchu (TW)

(21) Appl. No.: 18/469,014

(22) Filed: Sep. 18, 2023

(51) Int. Cl. H01L 23/00; H01L 21/48; H01L 23/373; H01L 23/498; H01L 23/522

(52) U.S. Cl. CPC H01L 24/32; H01L 21/486; H01L 23/3738; H01L 23/49816; H01L 23/5226; H01L 24/27; H01L 2224/274; H01L 2224/32225; H01L 2924/351

(57) ABSTRACT

A semiconductor structure can include a first substrate having a frontside and a backside opposite the frontside. The semiconductor structure can include devices on the frontside. The semiconductor structure can include first interconnect structures on the frontside and coupled to the devices. The semiconductor structure can include a heat distribution layer on the frontside and electrically isolated from the first interconnect structures, where the heat distribution layer includes a thermally conductive material. The semiconductor structure can include a second substrate coupled to the first substrate on the frontside. The semiconductor structure can include second interconnect structures on the backside and coupled to the devices.

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for smaller packaging techniques for semiconductor dies with improved performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, and 8 each illustrate a cross-sectional view of a portion of an example semiconductor package, in accordance with some embodiments.

FIG. 9 is an example flow chart of a method for fabricating a semiconductor package, in accordance with some embodiments.

FIGS. 10, 11, 12, 13, 14, 15, 16, 17, 18, 19, and 20 are cross-sectional views of a portion of an example semiconductor package at intermediate steps of the method of FIG. 9, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, the terms “about” and “approximately” generally mean plus or minus 10% of the stated value. For example, about 0.5 would include 0.45 and 0.55, about 10 would include 9 to 11, about 1000 would include 900 to 1100.

In general, semiconductor devices are fabricated by a combination of front end of line (“FEOL”) processes, which manufacture semiconductor (e.g., silicon) dies, and back end of line (“BEOL”) processes, which package one or more of these dies into a semiconductor device that can interface with other devices. For example, the package may combine a plurality of semiconductor dies and can be configured to be attached to a printed circuit board or other interconnected substrate, which may, in turn, allow the plurality of semiconductor dies of the semiconductor device to interface with additional semiconductor devices or other devices, power sources, communication channels, etc.

Semiconductor dies (or “dies” for short), as used herein, refers to as a portion of a semiconductor wafer having disposed thereupon one or more active circuits such as transistor logic, analog devices such as RF or filtering elements, diodes, other circuit components, or combinations thereof. A plurality of conductive features (e.g., vias and conductive lines) between the active surfaces can be disposed in one or more dielectric layers to form a plurality of metallization layers.

Physical demands for device miniaturization, increasing connectedness, and power efficiency are driving increases to semiconductor device density. Some of this increase in density can be attributed to improvements in the FEOL processes, including die miniaturization. Modern packaging technologies (e.g., package on package (POP), Fan-Out packaging (FO), system-on-integrated-chip (SoIC), etc.) are also driving miniaturization, intercommunication, power savings and other improvements. The one or more dies of these modern packages may be interconnected or connected to package inputs and/or outputs (I/O) by bond wires, through-silicon (or through-substrate) vias (TSVs), interconnect structures (e.g., vias and conductive lines disposed in various dielectric layers) coupled to the silicon dies, hybrid bonds via a bonding interface layer, solder bumps, other bonding methods, or combinations thereof. While such connections use sophisticated techniques, further improvements are needed to advance the state of the art.

For example, in existing packages that include power rail structures formed on both a frontside and backside of a device substrate, metallization layers are generally disposed along thermal dissipation paths between the device substrate and a heat sink. In this regard, thermal dissipation can be gated by such metallization layers (e.g., the dielectric layers thereof), leading to higher thermal resistance and higher temperature than packages having only one-sided (e.g., frontside) metallization layers. The present embodiments are generally directed to structures that can be integrated with existing packages to achieve reduction in the thermal resistance of the frontside and/or backside metallization layers.

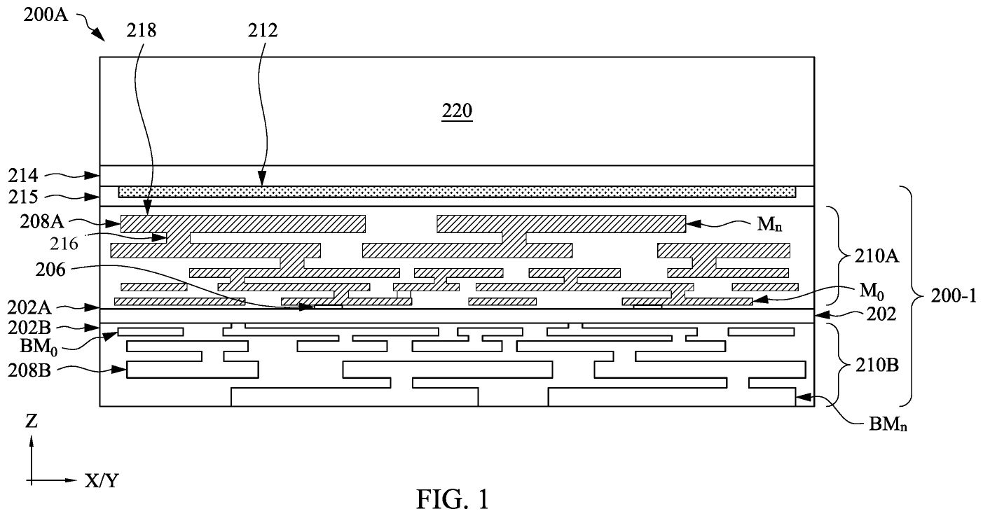

FIGS. 1-8 each illustrate a schematic diagram of a cross-sectional view of at least a portion of a semiconductor package (or chip) 200A-200H, respectively, in accordance with various embodiments. It should be appreciated that the example semiconductor packages 200A-200H of FIGS. 1-8 are merely illustrative embodiments, and are not intended to limit the scope of present disclosure. Hence, the example semiconductor packages 200A-200H can include various of other components (e.g., an interposer, one or more TSVs, an underfill material, an encapsulant material, etc.), while remaining within the scope of present disclosure.

Referring to FIG. 1, semiconductor package (or “package” for short) 200A includes a die 200-1 bonded to a carrier substrate 220 by a bonding layer 214. In the present embodiments, the die 200-1 includes at least a device substrate 202 and a plurality of active and/or passive device features 206 (e.g., transistors, resistors, capacitors, etc.) formed along (or over) a frontside 202A of the device substrate 202. The die 200-1 further includes a number of frontside metallization layers 210A (e.g., M₀, M₁, M₂, . . . , Mₙ, n being a positive integer) coupled to the device features 206 on the frontside 202A and a number of backside metallization layers 210B (e.g., BM₀, BM₁, BM₂, . . . , BMₙ, n being a positive integer) coupled to the device features 206 on a backside 202B of the device substrate 202 opposite the frontside 202A. In this regard, the carrier substrate 220 is bonded to the frontside 202A. As used herein, the term “coupled” refers to a physical, an electrical, and/or other suitable means of operatively connecting two components together. Further on the frontside 202A of the device substrate 202, the die 200-1 may optionally include a redistribution structure (not depicted) configured to reroute or redistribute the portions of the frontside metallization layers 210A.

In some embodiments, the device substrate 202 and the carrier substrate 220 each include a semiconductor material, such as silicon, doped or undoped, or an active layer of a semiconductor-on-insulator (SOI) substrate. The device substrate 202 and the carrier substrate 220 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. In the present embodiments, the frontside 202A of the device substrate 202 is configured as an active surface over which the device feature 206 are formed, and the backside 202B is configured as an inactive surface opposite the active surface. In the present embodiments, the carrier substrate 220 does not include any device features and may be configured to support the die 200-1 during subsequent processing steps.

The device features 206 may include any suitable active or passive devices formed along the frontside 202A of the device substrate 202. In some embodiments, the device features 206 include a plurality of transistors, such as fin-like field-effect transistors (FinFET), nanosheet transistors, gate-all-around (GAA) transistors, forksheet transistors, complementary FET (CFET), the like, or combinations thereof. In the present embodiments, the device features 206 are coupled to both the frontside metallization layers 210A and the backside metallization layers 210B. For example, the device features 206 may be coupled to the backside interconnect structures 208B via through-substrate (or through-silicon)-vias (TSVs; not depicted separately).

Each of the frontside metallization layers 210A and backside metallization layers 210B can include a number of conductive lines 218 and a number of vias 216, which are collectively referred to as frontside interconnect structures 208A and backside interconnect structures 208B, respectively, disposed in one or more dielectric layers (not depicted separately). In some embodiments, the conductive lines 218 are each formed as a conductive (e.g., metal) structure extending along a lateral direction (e.g., the X direction or the Y direction), and the vias 216 are each formed as a conductive (e.g., metal) structure extending along a vertical direction (e.g., the Z direction). Some of the device features 206 can be operatively coupled to each other (e.g., through a respective group of the frontside interconnect structures 208A and the backside interconnect structures 208B) to provide a respective function (e.g., a Boolean logic function).

In some embodiments, the interconnect structures 208A/208B include an electrically conductive material, such as copper, tungsten, aluminum, silver, gold, the like, or combinations thereof. The one or more dielectric layers of the metallization layers 210A/210B may include any suitable material, such as silicon oxide, a low-k dielectric material (e.g., having a dielectric constant less than that of silicon oxide, which is about 3.9) such as phosphosilicate glass (PSG), borosilicate glass (BSG), boron-doped phosphosilicate glass (BPSG), a tetraethyl orthosilicate (TEOS) based oxide, the like, or combinations thereof.

In the present embodiments, the die 200-1 further includes a heat distribution layer 212 disposed between the frontside interconnect structures 208A and the carrier substrate 220. The heat distribution layer 212 includes any suitable thermally conductive material, such as silicon, carbon nanotubes, carbon fibers, diamond, boron nitride, titanium nitride, titanium oxide, silicon carbide, aluminum nitride, beryllium oxide, aluminum, copper, gallium, germanium, gold, iron, magnesium, nickel, platinum, silver, titanium, tungsten, zinc, or combinations thereof. In some embodiments, the heat distribution layer 212 is compositionally homogenous and includes a single type of materials. In some embodiments, the heat distribution layer 212 is compositionally heterogeneous and includes at least two types of material described above. For example, the heat distribution layer 212 may include a metal layer disposed in or adjacent a non-metal layer.

In some embodiments, the heat distribution layer 212 is disposed in a dielectric layer 215 over the frontside interconnect structures 208A. In some embodiments, the heat distribution layer 212 and the dielectric layer 215 are collectively a portion of the frontside metallization layers 210A. The dielectric layer 215 may have a composition similar to that of the dielectric layers of the metallization layers 210A/210B described above. In some embodiments, the thermal conductivity of the heat distribution layer 212 is greater than the thermal conductivity of the dielectric layer 215 and/or the dielectric layers of the metallization layers 208A/208B. In some embodiments, the thermal conductivity of the heat distribution layer 212 is greater than the thermal conductivity of the frontside interconnect structures 208A. In some embodiments, the thermally conductive material may also be an electrically conductive material, such as any of the metals described above. In some embodiments, the thermally conductive material of the heat distribution layer 212 have the same composition as that of the interconnect structures 208A/208B.

In some embodiments, the thermally conductive material of the heat distribution layer 212 may be an electrically insulative or semiconductive material, such as any of the semiconductors and the dielectric materials above. For embodiments in which the thermally conductive material is also an electrically conductive material, the heat distribution layer 212 is physically and/or electrically isolated from (e.g., does not physically or electrically contact) the frontside interconnect structures 208A. For embodiments in which the thermally conductive material is an electrically insulative or semiconductive material, the heat distribution layer 212 may be physically and/or electrically coupled to the frontside interconnect structures 208A. Alternatively, the heat distribution layer 212 having a thermally conductive material that is an electrically insulative or semiconductive material may be physically and/or electrically isolated from the frontside interconnect structures 208A. As will be described in detail below, the heat distribution layer 212 improves the dissipation of heat generated during the operation of the device features 206.

In some embodiments, as depicted herein, the bonding layer 214 is disposed between the heat distribution layer 212 and the carrier substrate 220. In some embodiments, the bonding layer 214 is omitted and the heat distribution layer 212 is in direct contact with a surface (e.g., a bottom surface proximal to the device substrate 202) of the carrier substrate 220. The bonding layer 214 may include any suitable material, such as an oxide material.

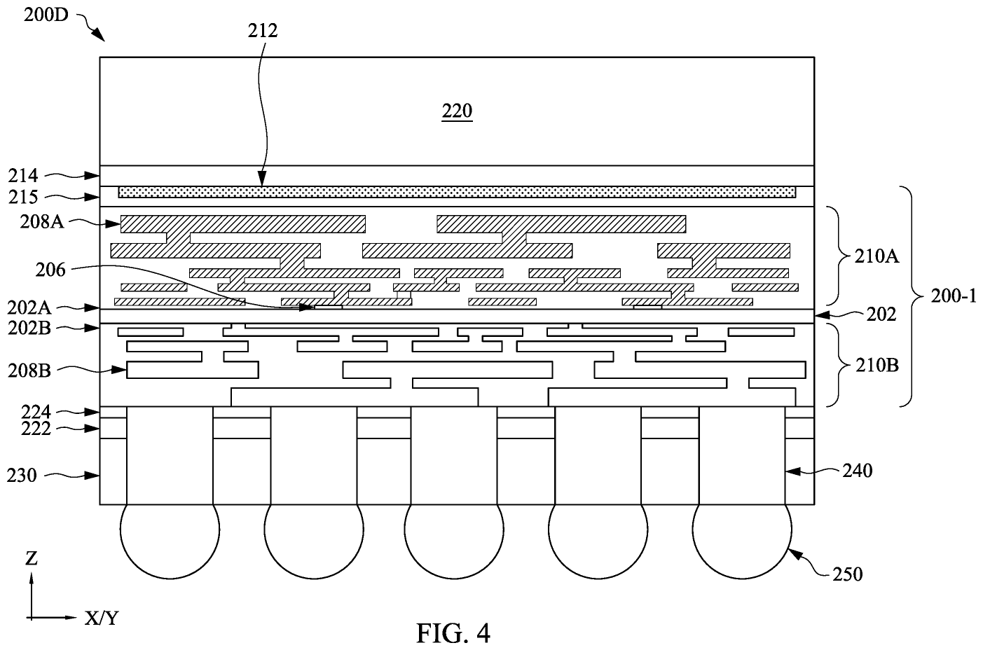

As the carrier substrate 220 includes a semiconductor material (i.e., having better thermal conductivity than the dielectric layers of the frontside metallization layers 210A), it generally acts as a heat sink for the device features 206. In this regard, the heat distribution layer 212, which is configured as a uniform layer of thermal conductor integrated with the frontside metallization layers 210A, allows any heat gated by the frontside metallization layers 210A to be more efficiently transferred to the carrier substrate 220, thereby reducing the thermal resistance of the frontside metallization layers 210A. In addition, as the bonding layer 214 generally includes a thermally insulative material, such as an oxide, inserting the heat distribution layer 212 near the bonding layer 214 improves removal of heat where it would otherwise accumulate before it reaches the heat sink that is the carrier substrate 220. As will be described in detail below (e.g., FIG. 4), depending on the structure of the package on the backside 202B, a heat distribution layer similar to the heat distribution layer 212 may be integrated with the backside metallization layers 210B to achieve similar effect at the backside 202B.

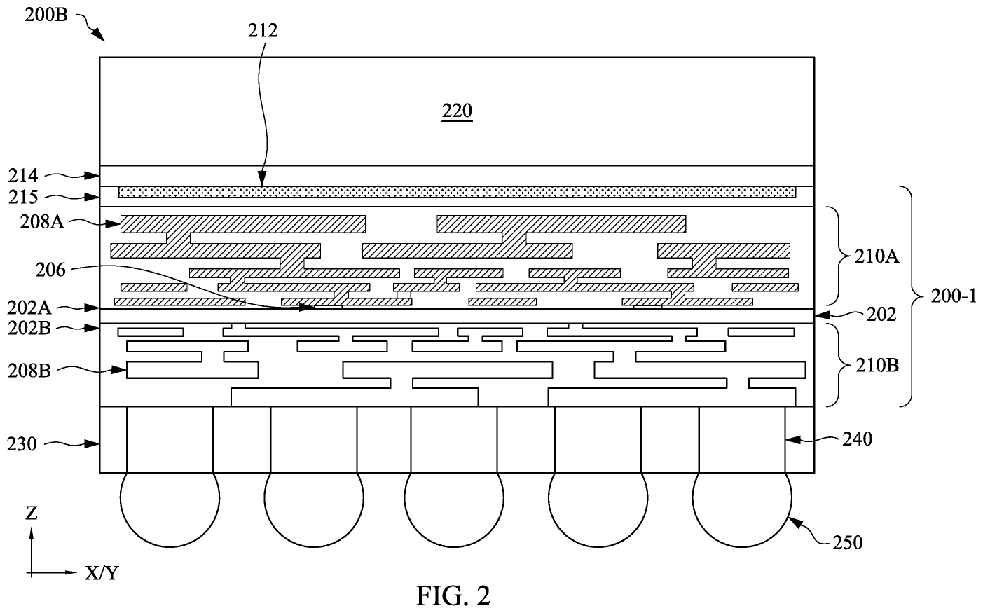

Referring to FIG. 2, package 200B is depicted to include the die 200-1 fused with (or bonded to) the carrier substrate 220 in an arrangement similar to the package 200A described above. In some embodiments, the die 200-1 is fused with the carrier substrate 220 by a bonding layer 214. However, different from the package 200A, the package 200B further includes a backside substrate 230 bonded to the backside metallization layers 210B. In other words, the backside metallization layers 210B are disposed between the device substrate 202 and the backside substrate 230. In some embodiments, though not depicted, the backside substrate 230 is bonded to the backside metallization layers 210B by a bonding layer similar to the bonding layer 214 described above.

In the present embodiments, still referring to FIG. 2, the package 200B includes a plurality of vias (e.g., TSVs) 240 embedded in (i.e., extending through) the backside substrate 230, where the vias 240 physically and/or electrically couple the backside interconnect structures 208B to a plurality of electrical connectors 250 configured to couple the die 200-1 to additional dies or package substrates. In some embodiments, the backside substrate 230 is an interpose configured to connect the die 200-1 to other dies similarly coupled to the backside substrate 230. In some embodiments, each of the vias 240 is coupled to a corresponding electrical connector 250 as depicted.

In the present embodiments, the backside substrate 230 includes one or more thermally conductive materials selected from silicon, carbon nanotubes, carbon fibers, diamond, boron nitride, titanium nitride, titanium oxide, silicon carbide, aluminum nitride, beryllium oxide, copper, gallium, and germanium. In some embodiments, the backside substrate 230 is free of any electrically conductive material, such as a metal. In some embodiments, the backside substrate 230 includes silicon, similar to the device substrate 202 and the carrier substrate 220. In this regard, the backside substrate 230 can be configured as an additional heat sink at the backside 202B, allowing heat to be dissipated from the backside of the device features 206. The vias 240 may include any suitable electrically and thermally conductive material, such as copper, tungsten, aluminum, silver, gold, the like, or combinations thereof, which may be similar to the composition of the interconnect structures 208A/208B. As such, the vias 240 electrically couple the backside interconnect structure 208B to the electrical connectors 250 and subsequently to additional chips or dies through the backside substrate 230. It is noted that, in the present embodiments, the backside substrate 230 does not include any device features, active or passive, formed along any of its surfaces, making it different from the device substrate 202 of the die 200-1.

The electrical connectors 250 may include ball grid array (BGA) connectors, solder balls, metal pillars, controlled collapse chip connection (C4) bumps, micro bumps, electroless nickel-electroless palladium-immersion gold technique (ENEPIG) formed bumps, the like, or combinations thereof. The electrical connectors 250 may be coupled to the corresponding vias 240 by any suitable means, such as under-bump metallizations (UBMs; not depicted). Further on the frontside 202A of the device substrate 202, the die 200-1 may optionally include a redistribution structure (not depicted) configured to reroute or redistribute the portions of the frontside metallization layers 210A.

Similar to the effect of the carrier substrate 220, the backside substrate 230 can serve as a heat sink or an intermediate thermal conductor for the device features 206 at the backside 202B. Such improvement in thermal dissipation at the backside 202B may be in addition to the improved thermal dissipation afforded by the heat distribution layer 212 at the frontside 202A, as depicted in the package 200A.

Furthermore, in existing implementations, electrical connectors such as those depicted herein are laterally separated by dielectric materials (e.g., low-k dielectric materials, similar to those of the metallization layers 210A/210B) for purposes of electrical isolation. These dielectric materials may introduce thermal insulation at an interface between any backside metallization layers and the electrical connectors. Additionally, due to their small contact area with the backside metallization layers relative to their size (e.g., a diameter of a C4 bump), heat generated by the device features 206 may have a limited path of conduction through the electrical connectors.

In the present embodiments, however, the backside substrate 230 disposed between the backside metallization layers 210B and the electrical connectors 250 includes a semiconductor material (e.g., silicon), which generally has a higher thermal conductivity than the dielectric materials in the existing implementations while still serving as an electrical insulator. In this regard, the backside substrate 230 can provide horizontal thermal dissipation (e.g., along the X direction or the Y direction), without creating substantial electrical conduction, between adjacent electrical connectors 250, thereby improving the thermal dissipation at the backside 202B.

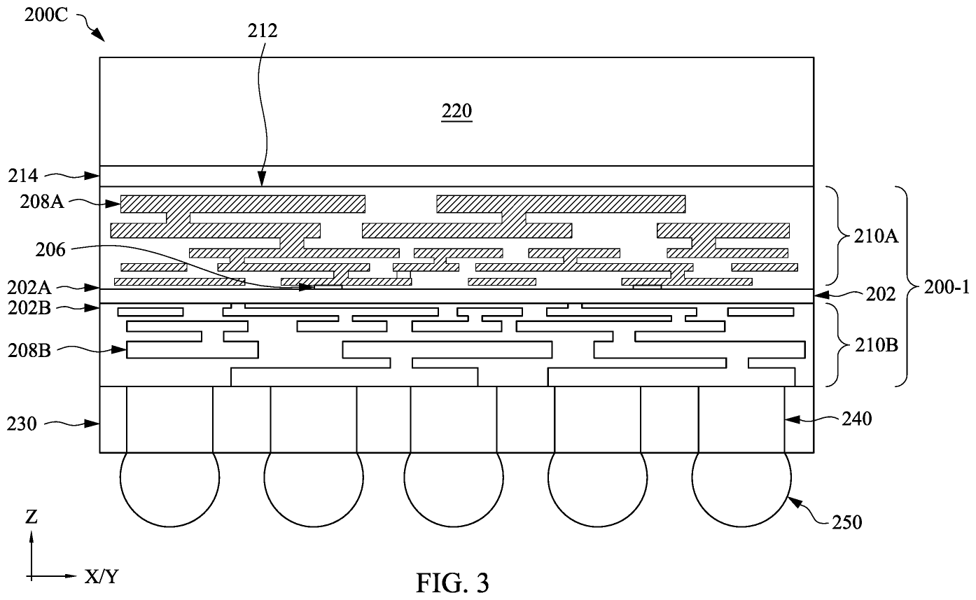

In some embodiments, the backside substrate 230 may be implemented independently from the heat distribution layer 212 at the frontside 202A. For example, referring to FIG. 3, the package 200C is depicted to have a structure similar to the package 200B with the exception that the heat distribution layer 212 is omitted from the frontside 202A. In this regard, the thermal dissipation improved mainly by the presence of the backside substrate 230 disposed at the backside 202B as described in detail above.

Referring to FIG. 4, package 200D is depicted to have structure similar to the package 200B with the exception that an additional heat distribution layer 224 is disposed between the backside metallization layers 210B and the backside substrate 230. In this regard, the vias 240 extend through the heat distribution layer 224 as well as the backside substrate 230 to couple the backside interconnect structures 208B to the electrical connectors 250. The heat distribution layer 224 is similar to the heat distribution layer 212 in composition and structure. For example, the heat distribution layer 224 includes at least one thermally conductive material with a thermal conductivity greater than that of the dielectric materials in the neighboring metallization layers 210A/210B. Examples of the thermally conductive materials are described in detail above. The heat distribution layer 224 may contribute to further thermal dissipation near dielectric components such as a bonding layer 222 coupling the backside substrate 230 to the device substrate 202. In some embodiments, the heat distribution layer 212 includes a thermally conductive but electrically insulative material, while the heat distribution layer 224 includes a thermally and electrically conductive material to provide interconnection between the backside interconnect structures 208B and any additionally dies or chips that are bonded to the electrical connectors 250.

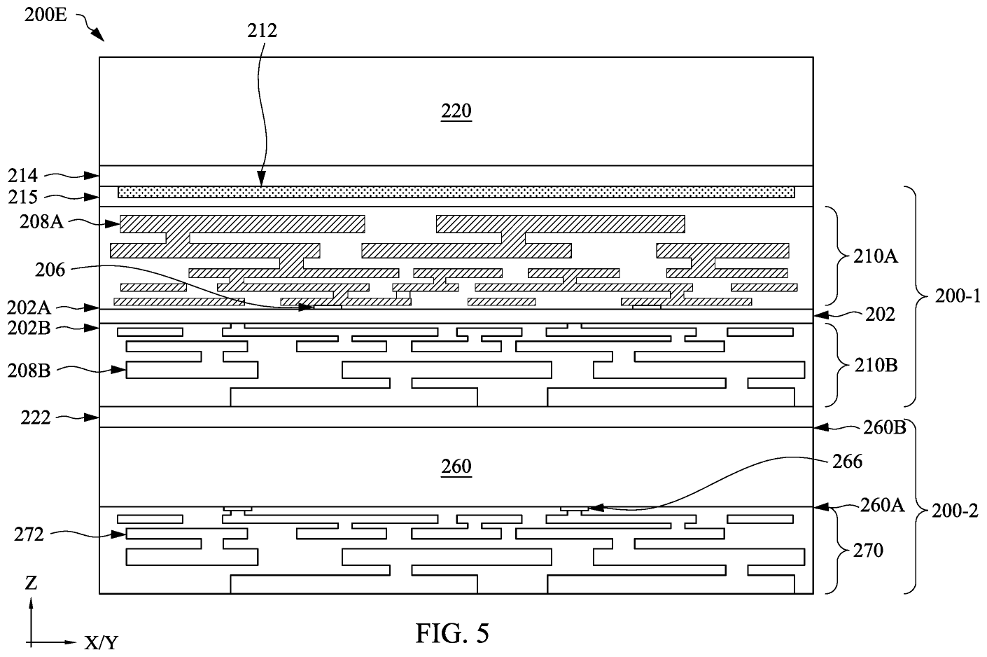

Referring to FIG. 5, package 200E is depicted to have an SoIC structure that includes an embodiment of the die 200-1 as an upper die (referred to as the upper die 200-1 in the package 200E) bonded to a die 200-2 as a lower die (referred to as the lower die 200-2 in the package 200E) by a bonding layer 222.

Components of the upper die 200-1 has been described in detail above. For example, as depicted in FIG. 5, the upper die 200-1 includes the device substrate 202, the frontside metallization layers 210A, the backside metallization layers 210B, the heat distribution layer 212, the carrier substrate 220, which is bonded to the frontside 202A by the bonding layer 214.

As depicted, the lower die 200-2 includes a device substrate 260 having a frontside (e.g., an active side) 260A opposite a backside 260B, where a plurality of device features 266 are formed along the frontside 260A. The lower die 200-2 further includes frontside metallization layers 270 disposed on the frontside 260A and coupled to the device features 266, where the frontside metallization layers 270 include a plurality of frontside interconnect structures 272. The depicted features of the lower die 200-2 are similar to those of the upper die 200-1 described in detail above. For example, the device substrate 260, the device features 266, and the frontside metallization layers 270 (and the frontside interconnect structures 272 by extension) may be similar to the device substrate 202, the device features 206, and the metallization layers 210A/210B, respectively. In some embodiments, though not depicted, the lower die 200-2 includes additional features consistent with the intended applications of the SoIC structure. For example, the lower die 200-2 may include vias (e.g., TSVs) extending through the device substrate 260 to electrically couple portions (e.g., the backside interconnect structures 208B) of the upper die 200-1 to portions (e.g., the device features 266) of the lower die 200-2.

In the present embodiments, the upper die 200-1 is bonded to the backside 260B of the device substrate 260 through the bonding layer 222, which may be similar to the bonding layer 214 described above. As such, the device substrate 260 may be configured as a heat sink for the backside of the upper die 200-1 in a manner similar to the backside substrate 230 of any of the packages 200B-200D described above.

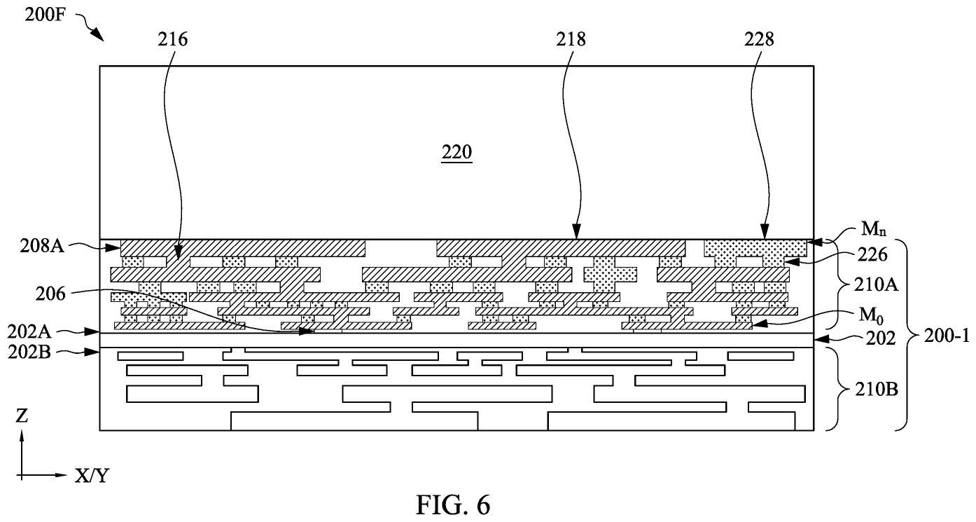

Referring to FIG. 6, the package 200F is depicted to have a structure similar to that of the package 200A with the exception that the frontside metallization layers 210A of the package 200F include dummy metal features within one or more of the frontside metallization layers 210A so as to provide additional paths of thermal conduction away from the device substrate 202 and towards the heat sink(s), which may include the carrier substrate 220 and the heat distribution layer 212, if included. For example, as depicted in FIG. 6, the die 200-1 includes dummy vias 226 and dummy conductive lines 228, collectively referred to as dummy metal features.

In some embodiments, the dummy vias 226 and the dummy conductive lines 228 are each configured with greater dimensions than their functional counterparts, namely the vias 216 and the conductive lines 218, respectively. For example, each of the dummy vias 226 may have a greater width (e.g., a lateral dimension along the X direction and/or the Y direction) than each of the vias 216, and each of the dummy conductive lines 228 may have a greater thickness (e.g., a vertical dimension along the Z direction) than each of the conductive lines 218. In some embodiments, the dimensions of the dummy metal features increase from the M₀ metallization layer toward the Mₙ metallization layer, which is closer to the heat sink, such as the carrier substrate 220, provided herein.

In some embodiments, the dummy metal features increase a density of the total metal features in the frontside metallization layers 210A by about 40% to about 85%. In some embodiments, the presence of the dummy vias 226 increases a density of vertical interconnect structures, including the vias 216 and the dummy vias 226, in the frontside metallization layers 210A by up to about 5%, such as by about 1%, 3%, or 5%. It is noted that the density of vertical interconnect structures (e.g., vias) in existing implementations without the dummy metal features provided herein is generally less than about 1%. Increase in the number of dummy metal features, such as the dummy vias 226, provide additional vertical thermal transfer (or conduction) paths away from the device features 206 (i.e., the device substrate 202), allowing for more efficient thermal dissipation towards the carrier substrate 220 and/or the heat distribution layer 212, if included.

In some embodiments, the dummy metal features may be placed in any suitable locations within the frontside metallization layers 210A without affecting, or significantly affecting, operations of the functional circuits or violating any design rules. In some examples, the dummy metal features may be electrically coupled to a power source. Alternatively, the dummy metal features are isolated from a power source and are considered “floating” features. In some examples, the dummy metal features may be placed at or near locations of higher heat production, referred to as “hot spots”, in the die 200-1. Alternatively or additionally, the dummy metal features may be placed in the backside metallization layers 210B to improve the thermal dissipation at the backside 202B.

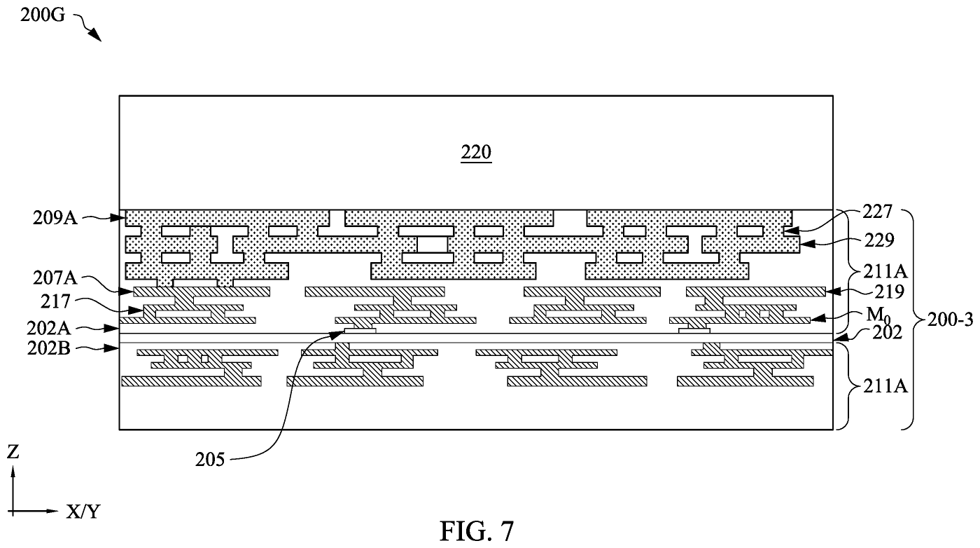

Referring to FIG. 7, the package 200G is depicted to include a die 200-3 bonded to the carrier substrate 220, where the die 200-3 includes the device substrate 202 having the frontside 202A and the backside 202B, a plurality of device features 205 on the frontside 202A, frontside metallization layers 211A, and backside metallization layers 211B. As depicted, the frontside metallization layers 211A each include a plurality of frontside interconnect structures 207A, which further include vias 217 and conductive lines 219. The die 200-3 differs from the die 200-1 of any of the packages 200A-200F in that the device features 205 are portions of various standard cell structures, some of which are configured for high toggle rate applications, such as clock tree, clock gating, high-speed channels, and memory read/write ports, and the like. Such standard cells may become hot spots during operation and may therefore also benefit from the addition of metal features in the frontside metallization layers 211A in a manner similar to that of the device features 206 benefiting from the dummy metal features 226 and 228.

In the present embodiments, the frontside metallization layers 211A further include frontside interconnect structures 209A coupled to the frontside interconnect structures 207A, where the frontside interconnect structures 209A include a plurality of vias 227 and conductive lines 229. The frontside metallization layers 211A are configured to provide additional thermal transfer (or conduction) paths for the standard cells on the device substrate 202. As such, the vias 227 and the conductive lines 229 in the frontside metallization layers 211A are collectively referred to as thermal-aware metal features.

As depicted in FIG. 7, the thermal-aware metal features may have dimensions (e.g., widths and thicknesses) greater than those of the vias 217 and the conductive lines 219, thereby increasing the density of the total metal features disposed over the frontside 202A. In contrast to the dummy metal features of the die 200-1, the thermal-aware metal features may be coupled to the frontside interconnect structures 207A during the circuit design stage to ensure that their placement complies with the design rules of the standard cells in the die 200-3.

In some embodiments, though not depicted, the packages 200F and 200G may each further include a heat distribution layer, similar to the heat distribution layer 212 of the package 200A, integrated with the frontside metallization layers 210A and 211A, respectively. In some embodiments, the packages 200F and 200G may each be coupled to a backside substrate, similar to the backside substrate 230 of the package 200B, or to another die, similar to the lower die 200-2 of the package 200E.

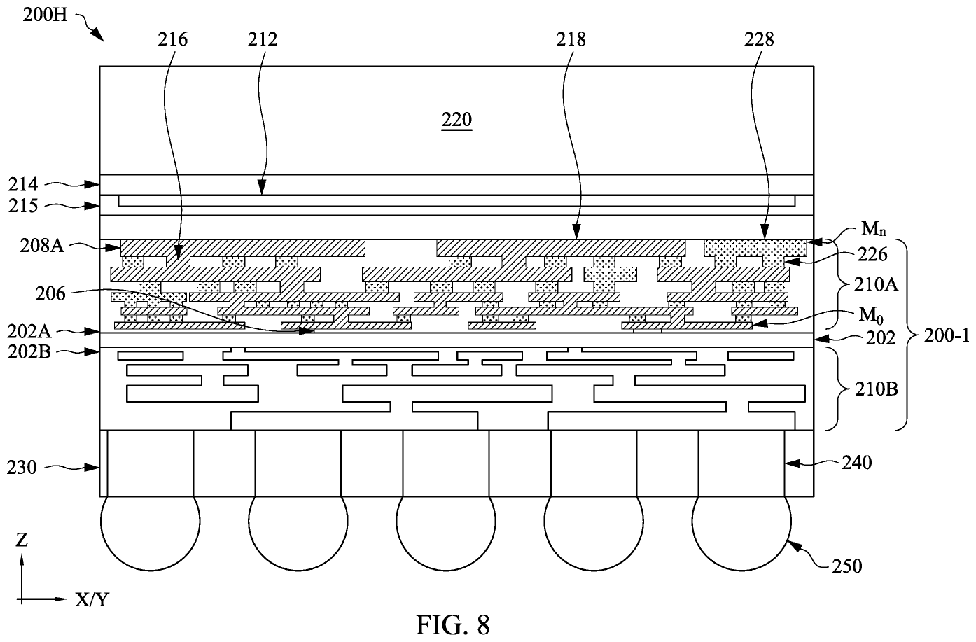

Referring to FIG. 8, package 200H incorporates the heat distribution layer 212, the backside substrate 230 coupled to the electrical connectors 250, and the dummy metal features as depicted in packages 200A, any of 200B-200D, and 200F, respectively. In this regard, thermal dissipation may be achieved from both the frontside 202A and the backside 202B of the device features 206, thereby reducing the overall thermal resistance and the temperature of the die 200-1 during operation.

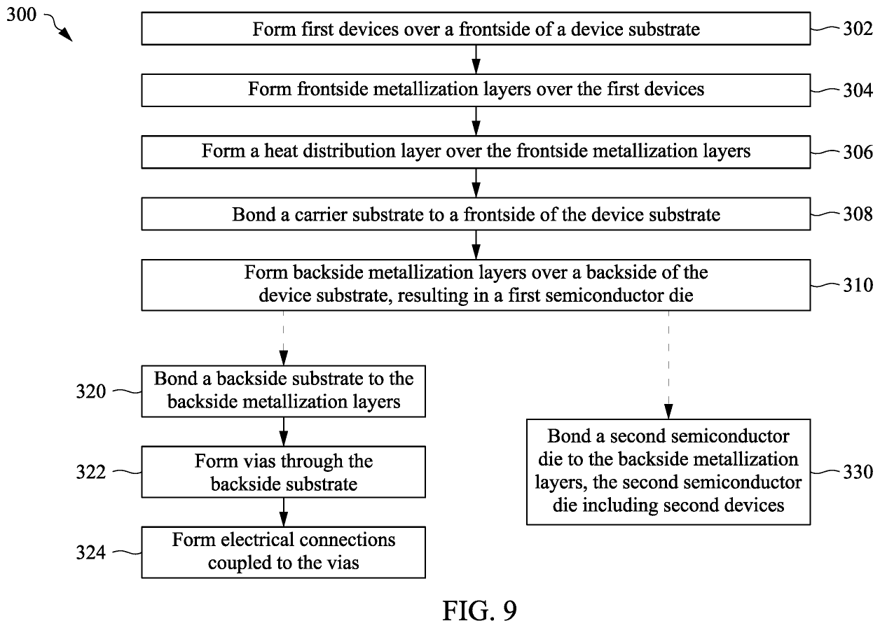

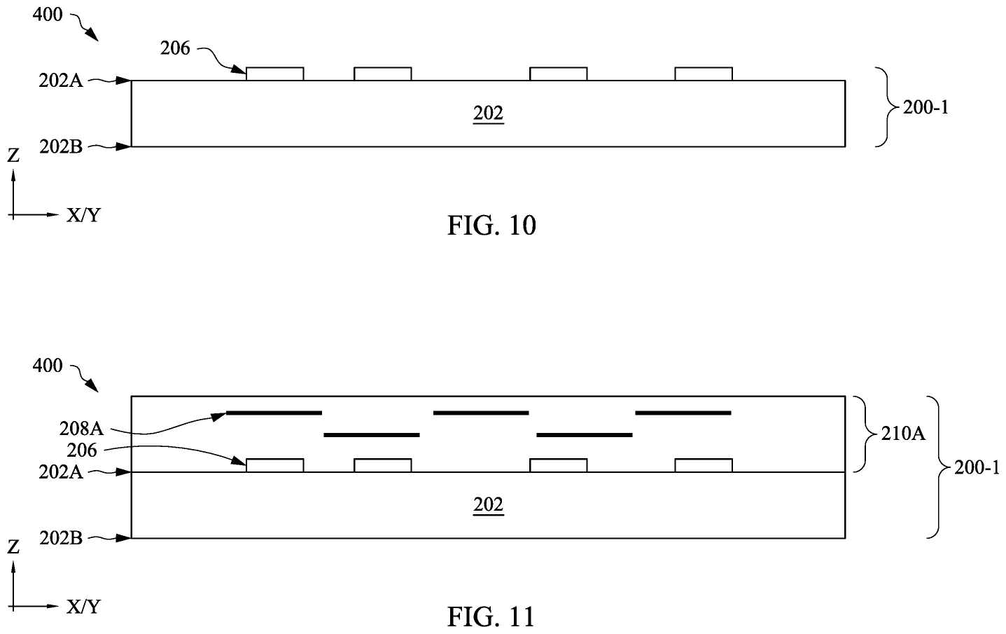

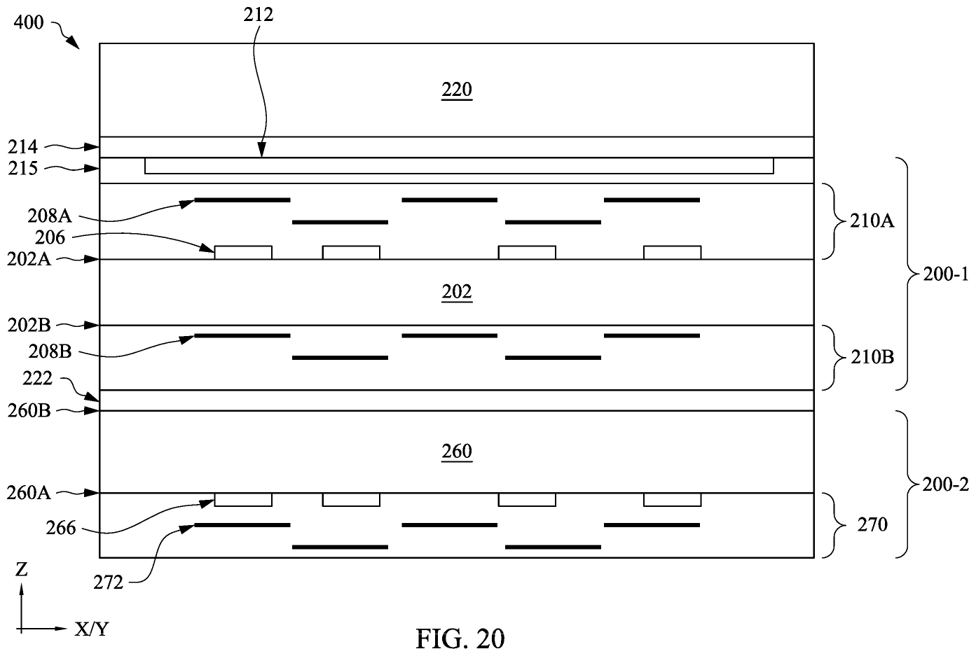

FIG. 9 illustrates a flow chart of an example method 300 for forming at least a portion of a package 400, in accordance with some embodiments of the present disclosure. The package 400 may include features similar to those of any one of the packages 200A-200H described above in reference to FIGS. 1-9, respectively. Accordingly, for purposes of simplicity, reference numbers describing features in the packages 200A-200H are repeated in the discussion of the method 300. It should be noted that the method 300 is merely an example, and is not intended to limit the present disclosure. Accordingly, it is understood that the order in which operations of the method 300 may be altered, that some of the operations may be omitted, and that additional operations may be provided before, during, and after the method 300. In accordance with some embodiments provided herein, operations of the method 300 may be discussed in conjunction to FIGS. 10-20.

Referring to FIG. 10, the method 300 at operation 302 forms the device features 206 over the device substrate 202.

The device substrate 202 may be a portion of a device wafer (not depicted) that includes a semiconductor material. The device features 206 may be first formed on the device wafer, which is subsequently singulated to form the die 200-1 that includes, inter alia, the device substrate 202. In some embodiments, the device substrate 202 includes silicon (e.g., a silicon wafer). In some embodiments, the device substrate 202 may be doped with a suitable dopant, depending on the types of device features 206 formed thereover. The device substrate 202 includes the frontside 202A opposite the backside 202B, where the device features 206 are formed along the frontside 202A. The device features 206 may be formed on or over the device substrate 202 by processes including, deposition, lithography, etching, other suitable processes, or combinations thereof.

Referring to FIG. 11, the method 300 at operation 304 forms the frontside metallization layers 210A (or 211A), which include the frontside interconnect structures 208A (or 207A, 209A), over the frontside 202A of the device substrate 202.

Each frontside metallization layer 210A (or 211A) includes a plurality of the frontside interconnect structures 208A (or 207A, 209A) formed in one or more dielectric layers (e.g., interlayer dielectric layers or intermetal dielectric layers; not depicted separately) described in detail above and configured to electrically connect the device features 206 with additional circuit components of the die 200-1 or other dies. As described in detail above, the frontside interconnect structures 208A and 207A include a plurality of vias (e.g., the vias 216 and the vias 217) and conductive lines (e.g., the conductive lines 218 and the conductive lines 219). In some examples, the dielectric layers may include a low-k dielectric material that is configured as a thermal and electrical insulator, i.e., having low thermal and electrical conductivity.

The frontside metallization layers 210A (or 211A) may be formed by one or more damascene processes or a series of deposition and patterning processes. For example, the damascene process may include depositing the dielectric layer over the device substrate 202, patterning the dielectric layer by a photolithography process to form one or more openings in the dielectric layer, depositing a conductive material described above to fill the openings, and performing one or more planarization process, such as a chemical-mechanical polishing/planarization (CMP) process, to form each of the frontside metallization layers 210A (or 211A). In some embodiments, the patterning of the dielectric layer is adjusted such that the openings may be formed to have different dimensions, allowing frontside interconnect structures (e.g., the dummy metal features and the thermal-aware metal features) of different sizes to be formed. Though not depicted, additional features, such as a passivation layer and/or a redistribution structure, may subsequently formed over the frontside metallization layers 210A.

In some embodiments, forming the frontside metallization layers 210A includes forming the dummy metal features (i.e., the dummy vias 226 and the dummy conductive lines 228), resulting in a structure of the package 400 that is similar to that of the package 200F described above. In some embodiments, forming the frontside metallization layers 211A includes forming the thermal-aware metal features (i.e., the vias 227 and the conductive lines 229), resulting in a structure of the package 400 that may be similar to that of the package 200G described above.

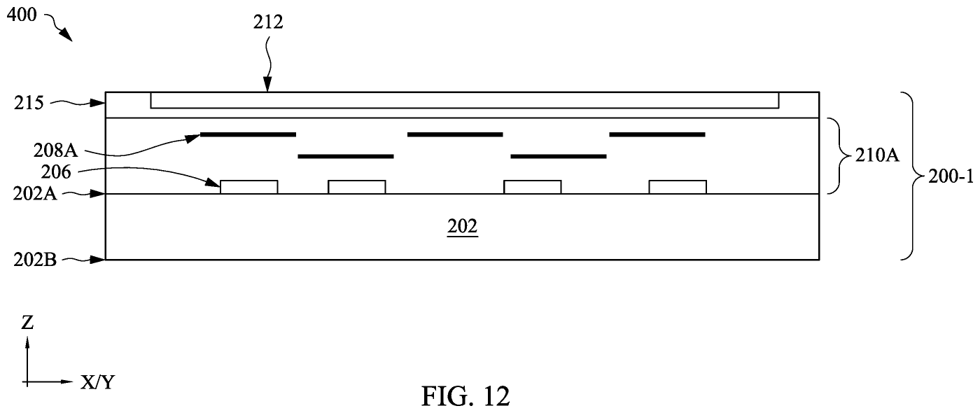

Referring to FIG. 12, the method 300 at operation 306 forms the heat distribution layer 212 over the frontside interconnect structures 208A (or 207A, 209A).

In some embodiments, forming the heat distribution layer 212 includes first forming a dielectric layer 215 over the frontside metallization layers 210A. The dielectric layer 215 may include any suitable material, such as silicon oxide, a low-k dielectric material described above, or the like. In some embodiments, the dielectric layer 215 is similar to the dielectric layers of the frontside metallization layers 210A. Subsequently, one or more of the thermally conductive materials described above are formed in the dielectric layer 215 by a suitable process, such as a damascene process described in detail above. The thermally conductive material may be deposited by a suitable method, such as chemical vapor deposition (CVD), spin-on-coating, atomic layer deposition (ALD), physical vapor deposition (PVD), plating (e.g., electroplating or electroless plating), the like, or combinations thereof. A CMP process may be performed to planarize the heat distribution layer 212.

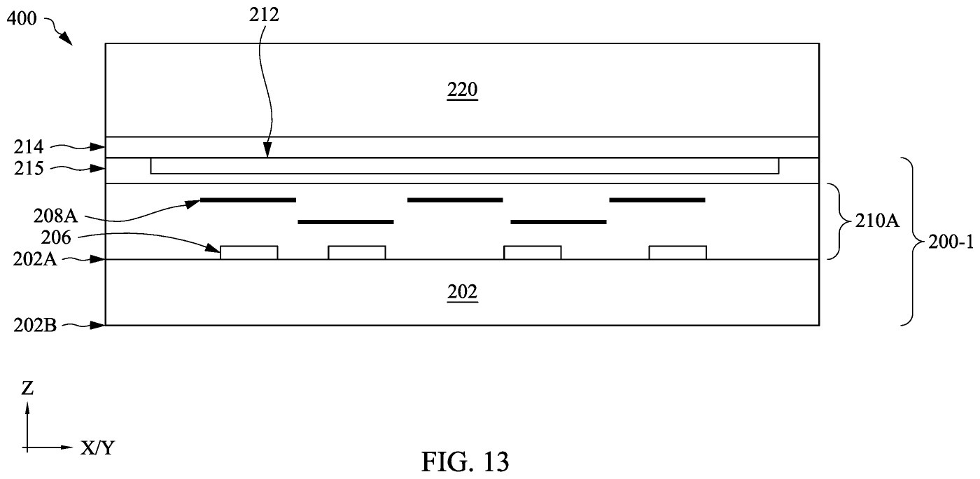

Referring to FIG. 13, the method 300 at operation 308 bonds the carrier substrate 220 to the frontside 202A of the device substrate 202.

In some embodiments, a first bonding layer (not depicted separately) is formed over the frontside 202A, such as over the heat distribution layer 212 and the dielectric layer 215, and a second bonding layer (not depicted separately) is formed over a surface of the carrier substrate 220. The first bonding and the second bonding layer may each include any suitable material, such as an oxide, and may be formed by any method, such as CVD, spin-on-coating, thermal oxidation, chemical oxidation, the like, or combinations thereof. The first bonding layer and the second bonding layer are then fused together by any suitable process, such as a pre-bonding process and an annealing process, to form the bonding layer 214, which couples the carrier substrate 220 to the device substrate 202.

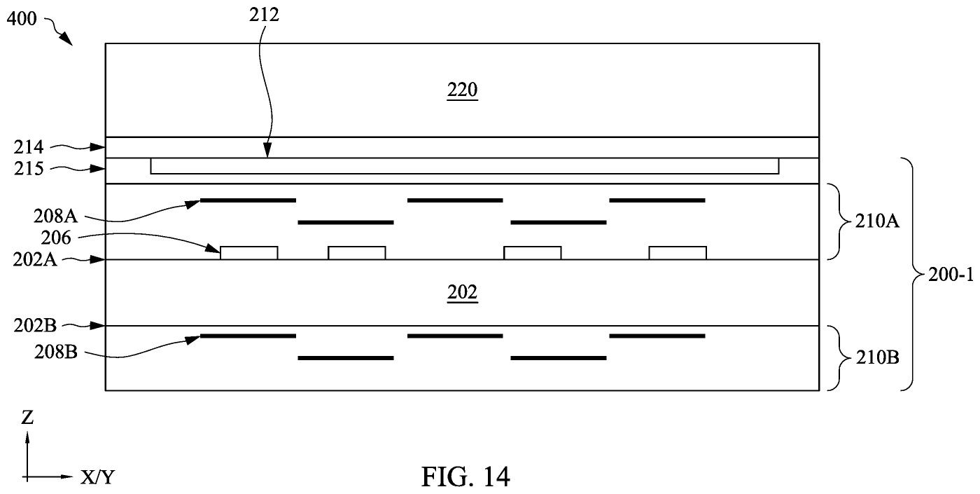

Referring to FIG. 14, the method 300 at operation 310 forms the backside metallization layers 210B, completing the formation of the die 200-1.

Structures of the backside metallization layers 210B, and methods of forming the same, may be similar to those of the frontside metallization layers 210A and are thus not repeated here for purposes of brevity. Though not depicted, forming the backside metallization layers 210B may include first inverting the package 400 such that it is supported by the carrier substrate 220. Subsequently, dielectric layers are deposited over the backside 202B and the backside interconnect structures 208B are formed in the dielectric layers by one or more damascene processes described above, resulting in a plurality of the backside metallization layers 210B. Thereafter, a bonding layer 222 is formed over the backside metallization layers 210B in preparation for bonding with additional features of the package 400. It is noted that the structure of the package 400 depicted in FIG. 14 is similar to that of the package 200A described above. Though not depicted, additional features, such as a passivation layer and/or a redistribution structure, may subsequently formed over the backside metallization layers 210B.

The method 300 may subsequently proceed in one of two paths. With respect to the first path, operations 320, 322, and 324 may be implemented to produce a structure of the package 400 similar to that of any of the packages 200B-200D described above. Alternatively, and with respect to the second path, operation 330 may be implemented to produce a structure of the package 400 similar to that of the package 200E described above.

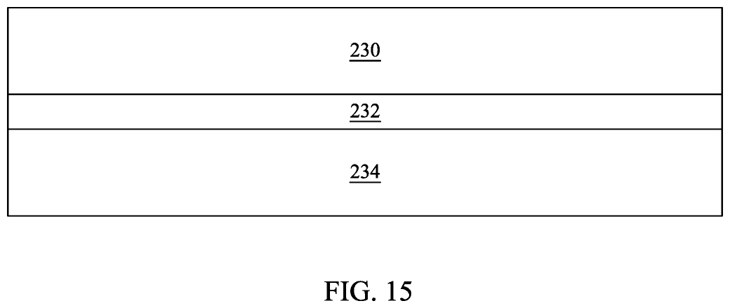

With respect to the first path, referring to FIGS. 15-17 collectively, the method 300 at operation 320 bonds the backside substrate 230 to the device substrate 202.

In some embodiments, referring to FIG. 15, bonding the backside substrate 230 includes first providing the backside substrate 230 bonded to a carrier substrate 234 by a de-bonding (or thermal-release) layer 232. The carrier substrate 234 may be similar to the carrier substrate 220 as described above. The de-bonding layer 232 may include an adhesive (e.g., epoxy)-based light-to-heat-conversion (LTHC) release material, which is configured to lose its adhesive property when heat is applied.

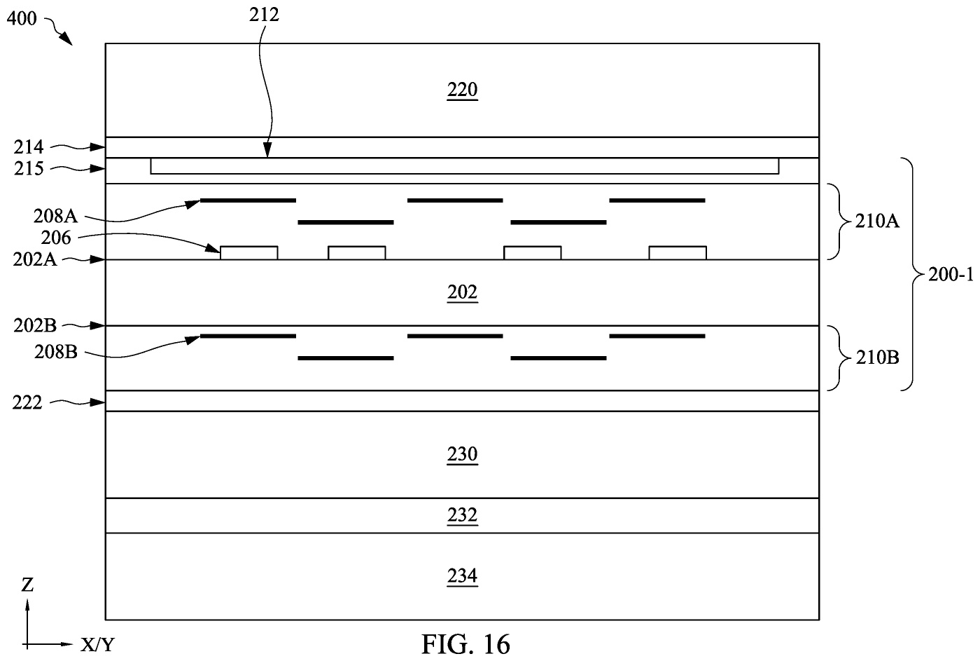

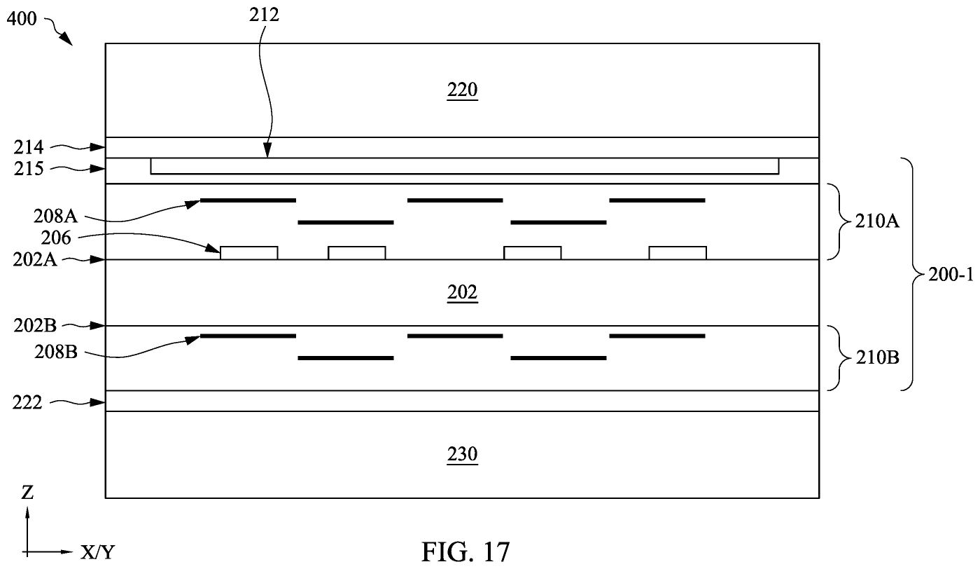

Referring to FIG. 16, bonding the backside substrate 230 proceeds to coupling the backside substrate 230, which is supported by the carrier substrate 234, to the backside 202B of the device substrate 202. Before performing the coupling process, a first bonding layer (not depicted separately) is applied to the backside 202B (e.g., over the backside metallization layers 210B) and a second bonding layer (not depicted separately) is applied to a surface of the backside substrate 230 opposite the carrier substrate 234. The first bonding layer and the second bonding layer are then fused together to form the bonding layer 222, thereby coupling the backside substrate 230 to the backside 202B. The bonding layer 222 may be similar to the bonding layer 214 described above. Subsequently, referring to FIG. 17, the carrier substrate 234 is removed from the backside substrate 230 by applying heat to the de-bonding layer 232. As a result, the backside metallization layers 210B are interposed between the device substrate 202 and the backside substrate 230.

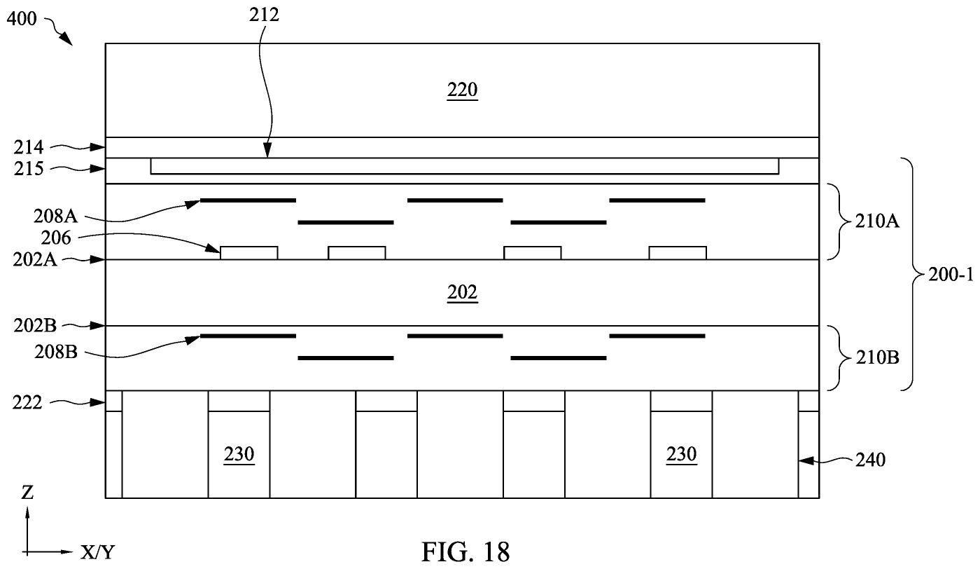

Referring to FIG. 18, the method 300 at operation 322 forms the vias 240 through the backside substrate 230, where the vias 240 are coupled to the backside metallization layers 210B.

The vias 240 may be formed in the backside substrate 230 by first patterning the backside substrate 230 to form a plurality of openings (not depicted). Subsequently, a suitable electrically and thermally conductive material described above is deposited in the openings. The conductive material is then planarized by a CMP process.

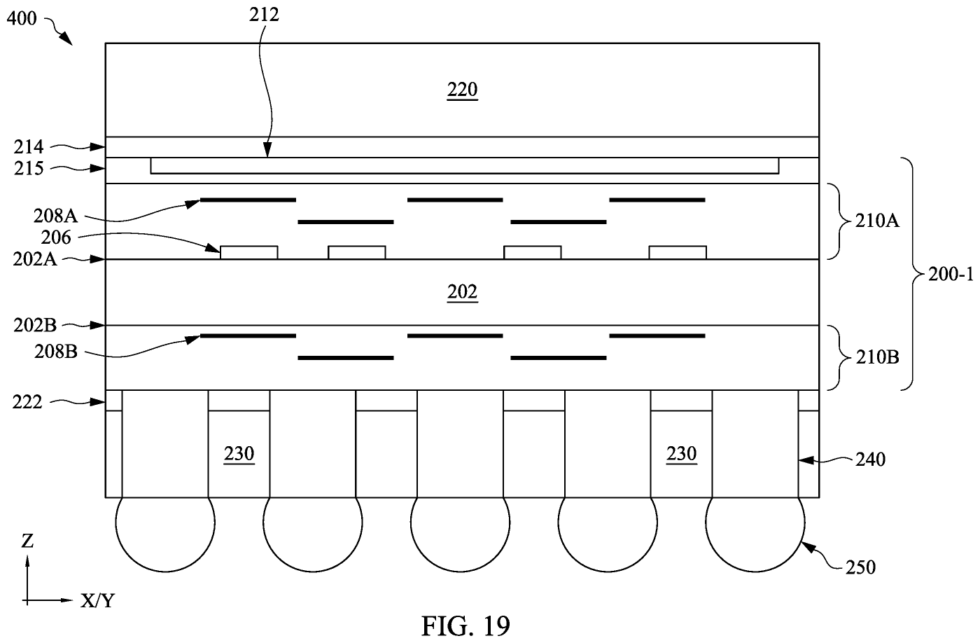

Referring to FIG. 19, the method 300 at operation 324 forms the electrical connectors 250 each coupled to a corresponding one of the vias 240.

The electrical connectors 250 may be formed by initially forming a layer of solder over a surface of the backside substrate 230 opposite the backside metallization layers 210B through evaporation, electroplating, printing, solder transfer, ball placement, or the like. Once the layer of solder has been formed on the structure, a reflow may be performed to shape the solder into the desired bump shapes. In some embodiments, the electrical connectors 250 include metal pillars, such as a copper pillar, formed by a sputtering, printing, electroplating, electroless plating, CVD, or the like, which are solder free and have substantially vertical sidewalls. A metal cap layer may be formed on top of the metal pillars. Structures such as UBMs may be formed over the surface of the backside substrate 230 before forming the electrical connectors 250, which is electrically coupled to the backside metallization layers 210B through the vias 240. The resulting structure of the package 400 may be similar to that of any of the packages 200B-200D described above.

With respect to the second path, the method 300 at operation 330 bonds the die 200-2, i.e., the lower die 200-2, to the die 200-1, i.e., the upper die 200-1, by the bonding layer 222 to form an integrated chip, such as an SoIC.

In some embodiments, the lower die 200-2 includes the device substrate 260 having the device features 266 formed along the frontside 260A and the frontside metallization layers 270 coupled to the device features 266. In this regard, the backside 202B of the upper die 200-1 is coupled to the backside 260B of the device substrate 260. The processes of forming the components of the lower die 200-2 and subsequently bonding the lower die 200-2 to the upper die 200-1 may be similar to those of described above with respect to operations 302-310 and 320, and are therefore not repeated for purposes of brevity. The resulting structure of the package 400 may be similar to that of the package 200E described above.

Though not depicted, the method 300 may include additional operations. For example, multiple packages 400 may be integrated (or stacked) together in any suitable configurations, while remaining within the scope of present disclosure.

In one aspect of the present disclosure, a semiconductor structure is provided. The semiconductor structure can include a first substrate having a frontside and a backside opposite the frontside. The semiconductor structure can include devices on the frontside. The semiconductor structure can include first interconnect structures on the frontside and coupled to the devices. The semiconductor structure can include a heat distribution layer on the frontside and electrically isolated from the first interconnect structures, where the heat distribution layer includes a thermally conductive material. The semiconductor structure can include a second substrate coupled to the first substrate on the frontside. The semiconductor structure can include second interconnect structures on the backside and coupled to the devices.

In another aspect of the present disclosure, a semiconductor structure is provided. The semiconductor structure can include a first substrate having a frontside and a backside opposite the frontside. The semiconductor structure can include devices on the frontside. The semiconductor structure can include first interconnect structures on the frontside and coupled to the devices. The semiconductor structure can include second interconnect structures on the backside and coupled to the devices. The semiconductor structure can include a second substrate coupled to the backside such that the second interconnect structures are between the first substrate and the second substrate. The semiconductor structure can include a via extending through the second substrate and coupled to the second interconnect structures.

In yet another aspect of the present disclosure, a method of fabricating a semiconductor structure is provided. The method can include forming a semiconductor die including devices over a frontside of a first substrate. The method can include forming first interconnect structures coupled to the devices on the frontside of the first substrate. The method can include bonding a second substrate to the frontside of the first substrate such that the first interconnect structures are between the first substrate and the second substrate. The method can include forming second interconnect structures over a backside of the first substrate opposite the frontside, resulting in a semiconductor die. The method can include bonding a third substrate to the backside of the first substrate. The method can include forming a plurality of vias coupled to the second interconnect structures and extending through the third substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first substrate having a frontside and a backside opposite the frontside;
devices on the frontside;
first interconnect structures on the frontside and coupled to the devices;
a heat distribution layer on the frontside and electrically isolated from the first interconnect structures, the heat distribution layer including a thermally conductive material;
a second substrate coupled to the first substrate on the frontside; and
second interconnect structures on the backside and coupled to the devices.

2. The semiconductor structure of claim 1, further comprising:
a third substrate on the backside of the first substrate; and
a plurality of vias extending through the third substrate and coupled to the second interconnect structures.

3. The semiconductor structure of claim 2, further comprising a plurality of conductive connectors each coupled to a corresponding one of the vias.

4. The semiconductor structure of claim 2, wherein the heat distribution layer is a first heat distribution layer, further comprising a second heat distribution layer between the second interconnect structures and the third substrate.

5. The semiconductor structure of claim 2, wherein the third substrate includes at least one thermally conductive material selected from the group consisting of silicon, carbon nanotubes, carbon fibers, diamond, boron nitride, titanium nitride, titanium oxide, silicon carbide, aluminum nitride, beryllium oxide, gallium, and germanium.

6. The semiconductor structure of claim 1, wherein the second substrate directly contacts the heat distribution layer.

7. The semiconductor structure of claim 1, further comprising:
a third substrate, wherein the second interconnect structures are between the first substrate and the third substrate;
second devices on a frontside of the third substrate; and
third interconnect structures coupled to the second devices.

8. The semiconductor structure of claim 1, wherein the thermally conductive material includes at least one material selected from the group consisting of silicon, carbon nanotubes, carbon fibers, diamond, boron nitride, titanium nitride, titanium oxide, silicon carbide, aluminum nitride, beryllium oxide, aluminum, copper, gallium, germanium, gold, iron, magnesium, nickel, platinum, silver, titanium, tungsten, and zinc.

9. A semiconductor structure, comprising:
a first substrate having a frontside and a backside opposite the frontside;
devices on the frontside;
first interconnect structures on the frontside and coupled to the devices;
second interconnect structures on the backside and coupled to the devices;
a second substrate coupled to the backside such that the second interconnect structures are between the first substrate and the second substrate; and
a via extending through the second substrate and coupled to the second interconnect structures.

10. The semiconductor structure of claim 9, further comprising:
a heat distribution layer over the first interconnect structures on the frontside; and
a third substrate over the heat distribution layer and coupled to the frontside.

11. The semiconductor structure of claim 10, wherein the heat distribution layer and the second substrate each include at least one material selected from the group consisting of silicon, carbon nanotubes, carbon fibers, diamond, boron nitride, titanium nitride, titanium oxide, silicon carbide, aluminum nitride, beryllium oxide, gallium, and germanium.

12. The semiconductor structure of claim 9, further comprising a conductive connector coupled to the via.

13. The semiconductor structure of claim 9, further comprising a bonding layer between the second interconnect structures and the second substrate.

14. The semiconductor structure of claim 9, wherein the first interconnect structures include conductive lines and vias, and wherein a density of the vias is about 1% to about 5%.

15. A method, comprising:
forming devices over a frontside of a first substrate;
forming first interconnect structures coupled to the devices on the frontside of the first substrate;
bonding a second substrate to the frontside of the first substrate such that the first interconnect structures are between the first substrate and the second substrate;
forming second interconnect structures over a backside of the first substrate opposite the frontside, resulting in a semiconductor die;
bonding a third substrate to the backside of the first substrate; and
forming a plurality of vias coupled to the second interconnect structures and extending through the third substrate.

16. The method of claim 15, further comprising forming a heat distribution layer between the first interconnect structures and the second substrate, the heat distribution layer including a thermally conductive material.

17. The method of claim 16, wherein the thermally conductive material includes at least one material selected from the group consisting of silicon, carbon nanotubes, carbon fibers, diamond, boron nitride, titanium nitride, titanium oxide, silicon carbide, aluminum nitride, beryllium oxide, aluminum, copper, gallium, germanium, gold, iron, magnesium, nickel, platinum, silver, titanium, tungsten, and zinc.

18. The method of claim 15, wherein the third substrate includes at least one thermally conductive material selected from the group consisting of silicon, carbon nanotubes, carbon fibers, diamond, boron nitride, titanium nitride, titanium oxide, silicon carbide, aluminum nitride, beryllium oxide, gallium, and germanium.

19. The method of claim 15, wherein bonding the third substrate includes:
providing the third substrate bonded to a fourth substrate by a de-bonding layer;
bonding the third substrate to the backside of the first substrate; and
releasing the de-bonding layer to remove the fourth substrate from the third substrate.

20. The method of claim 15, further comprising forming a plurality of conductive connectors each coupled to a corresponding one of the vias.
